(19) United States
(12) Patent Application Publication
(10) Pub. No.: US 2026/0051811 A1
(43) Pub. Date: Feb. 19, 2026

(54) Control Method and Power Controller for Power Factor Correction

(71) Applicant: Leadtrend Technology Corporation, Zhubei City (TW)

(72) Inventor: Yu-Pin WANG, Zhubei City (TW)

(21) Appl. No.: 19/191,191

(22) Filed: Apr. 28, 2025

(30) Foreign Application Priority Data
Aug. 14, 2024 (TW) 113130560

(51) Int. Cl. H02M 1/42; H02M 1/00; H03K 4/06

(52) U.S. Cl. CPC H02M 1/4225; H02M 1/0009; H03K 4/06

(57) ABSTRACT

Disclosed is a control method suitable for a PFC power converter, which includes a power switch and an inductive device. A compensation signal is provided based on an output voltage. A triangular-wave signal is provided based on the compensation signal. An average-current signal representing an average current flowing through the inductive device is provided. The triangular wave signal and the average-current signal are added up to provide an integrated signal. The compensation signal is compared with the integrated signal to stop an ON time of the power switch. By comparing the triangular-wave signal with the compensation signal, the triangular-wave signal resets and the ON time starts.

### CROSS-REFERENCE TO RELATED APPLICATION

This application claims priority to and the benefit of Taiwan Application Series Number 113130560 filed on Aug. 14, 2024, which is incorporated by reference in its entirety.

### BACKGROUND

The present disclosure relates generally to power factor correction (PFC) power converters, and more particularly to PFC power converters with a power controller that does not need a multiplier to achieve PFC.

Power factor (PF) represents how efficiently the supplied electrical power is utilized. The maximum power factor value is 1, which is considered ideal. When the power factor of an electronic device is less than 1, it indicates that the power supply system (such as an electric utility company) must have the ability of providing more power than the actual consumption of the electronic device to ensure its proper operation. To optimize the utilization of the power supply system's capacity, industrial regulations require many electronic devices, such as lighting electronics and power supplies above 75 W, to achieve a power factor of at least 0.9.

Active PFC can be achieved using a combination of an inductor and a power switch. By controlling the current flowing through the inductor with the power switch, the average inductor current is made approximately proportional to the input voltage, so the power factor is around 1.

Active PFC might use a power converter operating in discontinuous conduction mode (DCM). The advantage of DCM is that it enables soft switching, resulting in higher conversion efficiency and a simpler control circuit. However, it also has the potential drawback of increased electromagnetic interference (EMI) since, in each switching cycle, the inductor current must start from approximately zero amperes.

Conversely, some active PFC might use a power converter operating in continuous conduction mode (CCM). CCM results in lower EMI due to the smaller variations in inductor current. However, it is more challenging to control. For example, the control circuit often requires a complex and high-cost multiplier to determine the real-time inductor current, in order to have a good PF.

### BRIEF DESCRIPTION OF THE DRAWINGS

Non-limiting and non-exhaustive embodiments of the present invention are described with reference to the following drawings. In the drawings, like reference numerals refer to like parts throughout the various figures unless otherwise specified. These drawings are not necessarily drawn to scale. Likewise, the relative sizes of elements illustrated by the drawings may differ from the relative sizes depicted.

The invention can be more fully understood by the subsequent detailed description and examples with references made to the accompanying drawings, wherein:

FIG. 1 illustrates a PFC power converter according to the present invention;

FIG. 2 exemplifies a power controller in FIG. 1;

FIG. 3 exemplifies the structure of an averaging circuit;

FIG. 4 illustrates another power controller in one embodiment; and

FIG. 5 shows an exemplary waveform of a line voltage signal and an adjustment signal in one embodiment.

### DETAILED DESCRIPTION

In the following description, numerous specific details are set forth in order to provide a thorough understanding of the present invention. It will be apparent, however, to one having ordinary skill in the art that the specific detail need not be employed to practice the present invention. In other instances, well-known materials or methods have not been described in detail in order to avoid obscuring the present invention.

Reference throughout this specification to “one embodiment”, “an embodiment”, “one example” or “an example” means that a particular feature, structure, or characteristic described in connection with the embodiment or example is included in at least one embodiment of the present invention. Thus, appearances of the phrases “in one embodiment”, “in an embodiment”, “one example” or “an example” in various places throughout this specification are not necessarily all referring to the same embodiment or example. Furthermore, the particular features, structures, or characteristics may be combined in any suitable combinations and/or subcombinations in one or more embodiments or examples. Particular features, structures or characteristics may be included in an integrated circuit, an electronic circuit, a combinational logic circuit, or other suitable components that provide the described functionality. In addition, it is appreciated that the figures provided herewith are for explanation purposes to persons ordinarily skilled in the art and that the drawings are not necessarily drawn to scale.

Although the present invention is exemplified using a boost converter, it is not limited to this configuration. The invention may also be applicable to other power converters, such as flyback converters or buck-boost converters.

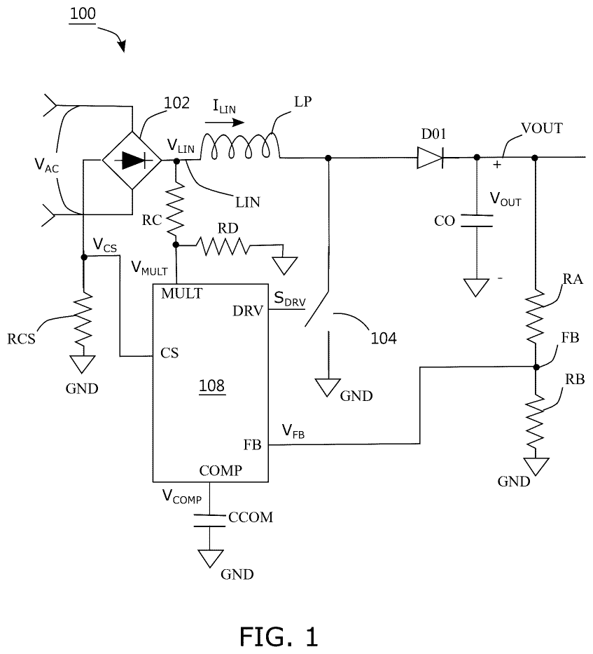

FIG. 1 illustrates PFC power converter 100 according to the present invention, featuring a boost converter architecture. PFC power converter 100 includes bridge rectifier 102, primary winding LP, power switch 104, current-sensing resistor RCS, power controller 108, resistors RA, RB, RC, and RD, output capacitor CO, compensation capacitor CCOM, and rectifier diode D01, interconnections of which are shown in FIG. 1. PFC power converter 100 provides output power source VOUT with output voltage V_{OUT}.

Bridge rectifier 102 performs full-wave rectification of AC mains voltage VAC, providing output terminals as power line LIN and current-sensing terminal CS. Current-sensing resistor RCS is connected between ground line GND and current-sensing terminal CS, providing to power controller 108 current-sensing signal V_{CS} at current-sensing terminal CS, which has a negative voltage relative to ground line GND. Ground line GND is considered to have a voltage of 0V, while power line LIN carries line voltage signal V_{LIN}. Ground line GND and power line LIN are powered by AC mains voltage VAC via bridge rectifier 102.

Primary winding LP (an inductive device) and power switch 104 are connected in series between power line LIN and ground line GND. Power controller 108 controls power switch 104 to regulate inductor current I_{LIN} flowing through primary winding LP. As current-sensing resistor RCS is substantially connected in series with power switch 104 and primary winding LP, the majority of inductor current I_{LIN} flows through current-sensing resistor RCS, substantially making current-sensing signal V_{CS} a representative of inductor current I_{LIN}.

Line voltage signal V_{LIN} is divided by the voltage divider consisting of resistors RC and RD to generate multiplication signal V_{MULT}, which is provided to power controller 108. Multiplication signal V_{MULT} is approximately in proportion to line voltage signal V_{LIN}.

The voltage divider formed by resistors RA and RB provides at feedback terminal FB feedback signal V_{FB}, which is approximately proportional to output voltage V_{OUT} and is sent to power controller 108. As will be explained later, power controller 108 compares feedback signal V_{FB} with predetermined voltage V_{REF} to generate compensation signal V_{COMP} on compensation capacitor CCOM. In other words, power controller 108 compares output voltage VOUT with a target voltage corresponding to predetermined voltage V_{REF} to establish compensation signal V_{COMP}.

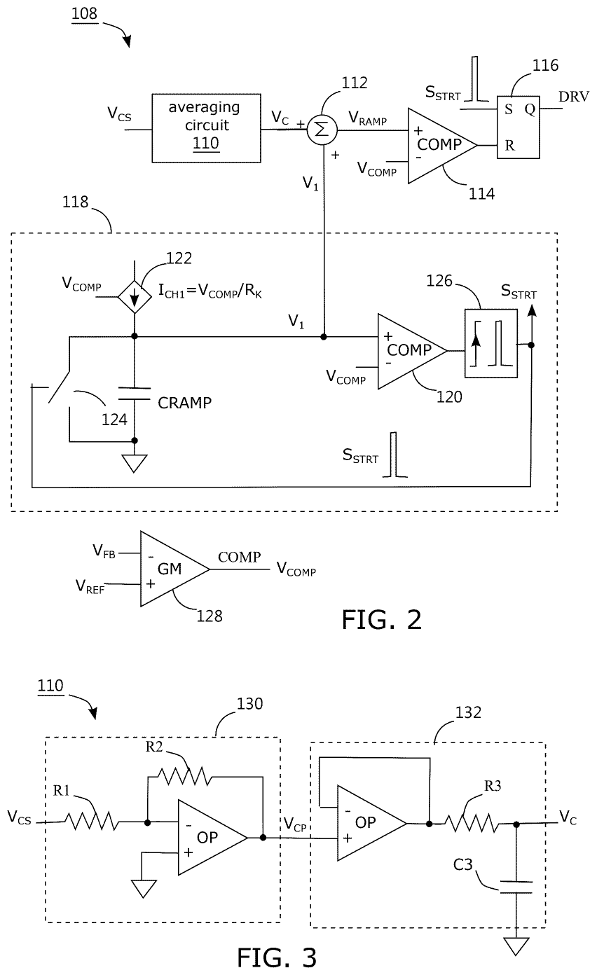

FIG. 2 exemplifies power controller 108 in FIG. 1, including averaging circuit 110, adder 112, comparator 114, SR flip-flop 116, triangle-wave generator 118, and transconductor 128. Power controller 108 can achieve power factor correction for PFC power converter 100 without a complex, costly multiplier.

Functioning as a compensation circuit, transconductor 128 compares predetermined voltage V_{REF} with feedback signal V_{FB}, equivalently comparing output voltage V_{OUT} with a target voltage corresponding to predetermined voltage V_{REF}. Transconductor 128 accordingly charges or discharges compensation capacitor CCOM to generate compensation signal V_{COMP} at one end of compensation capacitor CCOM.

Triangular-wave generator 118 provides triangular-wave signal V₁ based on compensation signal V_{COMP}. As illustrated in FIG. 2, voltage-controlled current source 122 generates charging current I_{CH1} according to compensation signal V_{COMP}, to charge capacitor CRAMP and to produce triangular-wave signal V₁. For example, charging current I_{CH1} is equal to compensation signal V_{COMP} divided by resistance value R_{K}, meaning compensation signal V_{COMP} determines the rising slope of triangular-wave signal V₁. Comparator 120 compares triangular-wave signal V₁ with compensation signal V_{COMP}. Triangular-wave generator 118 can also function as a clock generator. When triangular-wave signal V₁ exceeds compensation signal V_{COMP}, comparator 120 triggers pulse generator 126 to issue reset pulse S_{STRT}. Reset pulse S_{STRT} resets triangular-wave signal V₁ to its initial state of 0V via switch 124, starting the next clock cycle. Thus, clock period Ts set by triangular-wave generator 118 can be expressed as follows:

$${T}_{S} = {C}_{R A M P} * {V}_{C O M P} / {I}_{CH 1} = {C}_{R A M P} * {R}_{K} , \qquad ( 1 )$$

where CRAMP is the capacitance of capacitor CRAMP. Reset pulse S_{STRT} also sets SR flip-flop 116, starting ON time TON of power switch 104. ON time TON refers to the duration during which power switch 104 is in a short-circuit conduction state, electrically connecting one end of primary winding LP to ground line GND, and length T_{ON} stands for the length of ON time TON.

Averaging circuit 110 generates average current signal V_{C} based on current-sensing signal V_{CS}, representing average current Ī_{LIN} flowing through primary winding LP. Simply put, V_{C}=K*Ī_{LIN}, where K is a predetermined constant, the ratio of average current signal V_{C} to average current Ī_{LIN}.

As shown in FIG. 2, adder 112 adds up average current signal V_{C} and triangular-wave signal V₁ to generate integrated signal V_{RA}MP, and comparator 114 compares integrated signal VRAMP with compensation signal V_{COMP}. When integrated signal V_{RA}MP is greater than or equal to compensation signal V_{COMP}, comparator 114 resets SR flip-flop 116, ending ON time TON of power switch 104. Therefore, when ON time TON ends, the following equation can be derived from the circuit in FIG. 2.

$$\begin{matrix}{V}_{C} = {V}_{COMP} - {V}_{1} \\ = {V}_{COMP} - {I}_{CH 1} ⋆ {T}_{ON} / {C}_{RAMP} \\ = {V}_{COMP} - {V}_{COMP} / {R}_{K} ⋆ {T}_{ON} / {C}_{RAMP} \\ = {V}_{COMP} ⋆ ( 1 - {T}_{ON} / ( {R}_{K} ⋆ {C}_{RAMP} ) ) \\ = {V}_{COMP} ⋆ ( 1 - {T}_{ON} / {T}_{S} ) \\ = {V}_{COMP} ⋆ ( {T}_{OFF} / {T}_{S} )\end{matrix} , \qquad ( 2 )$$

Where length T_{OFF} stands for the length of OFF time TOFF, which refers to the period of time when power switch 104 is in an open-circuit state, disconnecting primary winding LP from ground line GND.

If PFC power converter 100 in FIG. 1 operates in CCM, line voltage signal V_{LIN}, output voltage V_{OUT}, length T_{ON} of ON time TON, and clock period Ts will have the following relationship shown in equation (3).

$${V}_{LIN} / {V}_{OUT} = {T}_{OFF} / {T}_{S} . \qquad ( 3 )$$

Combining Equations (2) and (3), the following Equation (4) can be derived.

$${V}_{C} = {V}_{C O M P} * {V}_{LIN} / {V}_{OUT} . \qquad ( 4 ) .$$

$${\overline{I}}_{L I N} = {V}_{COMP} * {V}_{L I N} * / ( {V}_{OUT} * K )$$

At steady state, output voltage V_{OUT} an compensation signal V_{COMP} are generally stable values. Therefore, from Equation (4), it can be observed that average current Ī_{LIN} is proportional to line voltage signal V_{LIN}, achieving the purpose of power factor correction.

FIG. 3 exemplifies the structure of averaging circuit 110, which consists of two cascaded stages. First stage 130 functions as an amplifier that, with resistors R1 and R2, amplifies the negative-voltage current-sensing signal V_{CS} and converts it into positive-voltage sensing signal V_{CP}. Second stage 132 acts as a low-pass filter, using resistor R3 and capacitor C3 to low-pass filter sensing signal V_{CP}, thereby providing average current signal V_{C}.

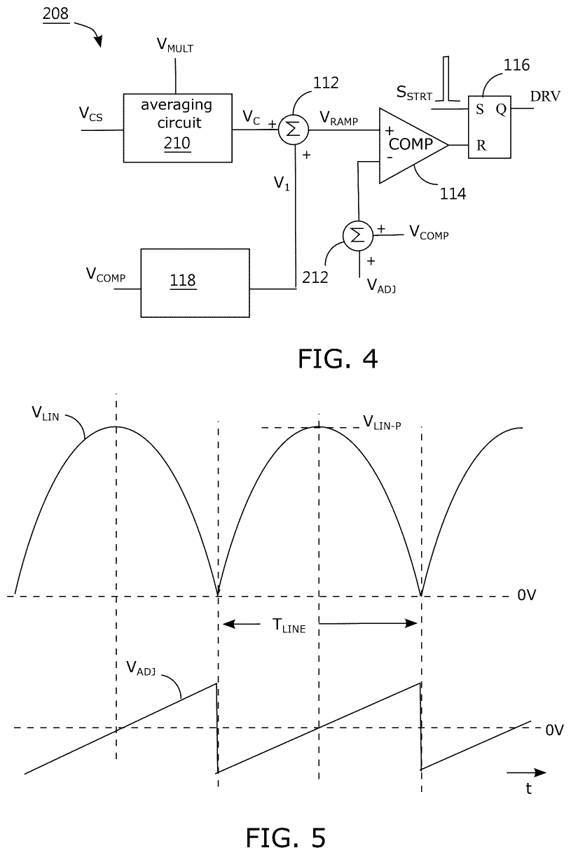

FIG. 4 illustrates power controller 208, which can replace power controller 108 in FIG. 1 in one embodiment. The portions of power controller 208 that are identical or similar to those in power controller 108 can be understood based on the previous description and will not be redundantly explained.

In power controller 208, averaging circuit 210 determines the relationship between average current signal V_{C} and average current Ī_{LN} based on multiplication signal V_{MULT}, which is proportional to line voltage signal V_{LIN}. Averaging circuit 210 senses multiplication signal V_{MULT} to determine peak value V_{LIN-P} of line voltage signal V_{LIN}, so as to determine the ratio of average current signal V_{C} to average current Ī_{LIN}. For example, when peak value V_{LIN-P} of line voltage signal V_{LIN} is greater than 150V, V_{C}=KH*Ī_{LIN}; and when peak value V_{LIN-P} is less than 150V, V_{C}=KL*Ī_{LIN}, where KH and KL are two different ratios of average current signal V_{C} to average current Ī_{LIN}, with KH being greater than KL. For example, averaging circuit 110 has the resistance of resistor R1 changed if peak value V_{LIN-P} changes from 240V into 110V. This adjustment allows the control loop to be operable over a wider and more appropriate range.

In FIG. 4, adjustment signal V_{ADJ} is applied through adder 212 to modify compensation signal V_{COMP}, to improve total harmonic distortion (THD) or power factor. To reduce or eliminate EMI, an additional filter capacitor can be added and connected between power line LIN and current-sensing terminal CS in FIG. 1. However, due to the time-varying nature of line voltage signal V_{LIN}, this filter capacitor generates a capacitive current with a 90-degree phase shift relative to line voltage signal V_{LIN}. As a result, this filter capacitor affects the impedance seen from the two terminals supplying AC mains voltage VAC. In power controller 208, adder 212 adjusts compensation signal V_{COMP} with adjustment signal V_{ADJ} to slightly modify average current Ī_{LIN}. This possibly compensates the adverse effect of the filter capacitor on power line LIN, allowing the impedance seen at the terminals of AC mains voltage VAC to be closer to a pure resistance. As a result, this enhances power factor correction and reduces total harmonic distortion.

FIG. 5 shows an exemplary waveform of line voltage signal V_{LIN} and adjustment signal V_{A}DJ in one embodiment. Line voltage signal V_{LIN} exhibits an M-shaped waveform with cycle period T_{LINE} of approximately 1/100 or 1/120 seconds. Peak value V_{LIN-P} may be 240V, 110V, or 100V for example, depending on AC mains voltage VAC. In FIG. 5, adjustment signal V_{ADJ} is generally a sawtooth wave, generated in response to multiplication signal V_{MULT} or line voltage signal V_{LIN}. At the beginning of cycle period T_{LINE} (when line voltage signal V_{LIN} starts rising from its lowest point inside the valley), adjustment signal V_{ADJ} is reset to be at its minimum and is negative. At the end of cycle period T_{LINE} (when line voltage signal V_{LIN} is about to reach its lowest point), adjustment signal V_{ADJ} is at its maximum and is positive. When line voltage signal V_{LIN} decreases, the filter capacitor on power line LIN discharges, and adjustment signal V_{ADJ} causes PFC power converter 100 to draw more current. Conversely, when line voltage signal V_{LIN} increases, the filter capacitor absorbs current, and adjustment signal V_{ADJ} causes PFC power converter 100 to draw less current. Accordingly, adjustment signal V_{ADJ} helps to compensate the effect on PF that the filter capacitor causes.

While the invention has been described by way of examples and in terms of preferred embodiments, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A control method in use of a power controller in a PFC power converter, wherein the PFC power converter comprises a power switch and an inductive device, the control method comprising;
providing a compensation signal according to an output voltage of the PFC power converter;
generating a triangular-wave signal in response to the compensation signal;
providing an average current signal to present an average current flowing through the inductive device;
adding up the average current signal and the triangular-wave signal to generate an integrated signal; and
comparing the integrated signal with the compensation signal to end an ON time of the power switch.

2. The control method of claim 1, further comprising:
comparing the triangular-wave signal with the compensation signal to start the ON time.

3. The control method of claim 2, further comprising:
resetting the triangular-wave signal when the triangular-wave signal exceeds the compensation signal.

4. The control method of claim 1, comprising:
making a slope of the triangular-wave signal in proportion to the compensation signal.

5. The control method of claim 1, comprising:
producing a sensing signal in proportion to an inductor current through the inductive device; and
low-pass filtering the sensing signal to provide the average current signal.

6. The control method of claim 5, comprising:
converting a current-sensing signal into the sensing signal, wherein the current-sensing signal is generating by a current-sensing resistor connected between a ground line and a bridge rectifier rectifying an AC mains voltage, and the current-sensing signal and the sensing signal are different in polarity.

7. The control method of claim 6, comprising:
receiving a multiplication signal in proportion to a line voltage signal at a power line;
determining a peak value of the line voltage signal in response to the multiplication signal; and
determining a ratio of the average current signal to the average current according to the peak value.

8. The control method of claim 7, comprising:
providing an adjustment signal in response to the line voltage signal; and
ending the ON time of the power switch when the integrated signal exceeds the summation of the compensation signal and the adjustment signal.

9. The control method of claim 1, comprising:
providing a charging current according to the compensation signal; and
producing the triangular-wave signal on a capacitor by using the charging current to charge the capacitor.

10. A power controller in use of a PFC power converter with a power switch and an inductive device, wherein the PFC power converter providing an output power source with an output voltage, the power controller comprising:
a compensation circuit comparing the output voltage with a target voltage to provide a compensation signal;
a triangular-wave generator providing a triangular-wave signal based on the compensation signal;
an averaging circuit providing an average current signal to represent an average current flowing through the inductive device; and
a first comparator comparing the compensation signal with an integrated signal to end an ON time of the power switch, wherein the integrated signal is a summation of the average current signal and the triangular-wave signal.

11. The power controller of claim 10, wherein the triangular-wave generator comprises:
a capacitor; and
a voltage-controllable current source providing a charging current according to the compensation signal;
wherein the charging current charges the capacitor to generate the triangular-wave signal.

12. The power controller of claim 11, wherein the triangular-wave generator comprises a second comparator comparing the triangular-wave signal with the compensation signal to start the ON time.

13. The power controller of claim 12, wherein the second comparator resets the triangular-wave signal when the triangular-wave signal exceeds the compensation signal.

14. The power controller of claim 10, wherein the averaging circuit comprises:
an amplifier converting a current-sensing signal into a sensing signal, wherein the current-sensing signal and the sensing signal are different in polarity; and
a low-pass filter for low-pass filtering the sensing signal to generate the average current signal;
wherein the current-sensing signal is generated by a current-sensing resistor connected in series with the inductive device.

15. The power controller of claim 14, wherein the amplifier determines a ratio of the average current signal to the average current based on a peak value of a line voltage signal at a power line connected to the inductive device.

16. The power controller of claim 15, wherein the first comparator stops the ON time when the integrated signal exceeds a summation of an adjustment signal and the compensation signal, and the adjustment signal is generated in response to the line voltage signal.

17. A PFC power converter, comprising:
the power controller of claim 10, wherein the compensation circuit compares a feedback signal with a predetermined voltage to generate the compensation signal;
the power switch and the inductive device connected in series between a power line and a ground line; and
a first voltage divider providing the feedback signal in response to the output voltage of the PFC power converter.

18. The PFC power converter of claim 17, comprising:
a bridge rectifier rectifying an AC mains voltage to power the power line and the ground line; and
a second voltage divider providing a multiplication signal in proportion to a line voltage signal at the power line;
wherein the averaging circuit determines a ratio of the average current signal to the average current based on a peak value of the line voltage signal.

19. The PFC power converter of claim 18, wherein the first comparator stops the ON time when the integrated signal exceeds a summation of an adjustment signal and the compensation signal, and the adjustment signal is generated in response to the line voltage signal.

20. The PFC power converter of claim 17, wherein the triangular-wave generator makes a slope of the triangular-wave signal in proportion to the compensation signal, and compares the triangular-wave signal with the compensation signal to start the ON time.
